(19) United States
(12) Patent Application Publication
(10) Pub. No.: US 2022/0228734 A1
(43) Pub. Date: Jul. 21, 2022

(54) TOUCH CONTROL LAMP

(71) Applicants: Mark SETTEDUCATI, Loudon, TN (US); Robert W. JEFFWAY, Jr., Leeds, MA (US)

(72) Inventors: Mark SETTEDUCATI, Loudon, TN (US); Robert W. JEFFWAY, Jr., Leeds, MA (US)

(21) Appl. No.: 17/609,556

(22) PCT Filed: May 7, 2020
(86) PCT No.: PCT/US20/31820

§ 371 Date: Nov. 8, 2021

Related U.S. Application Data
(60) Provisional application No. 62/845,838, filed on May 9, 2019.

(51) Int. Cl. F21V 23/04; F21V 19/00; F21V 29/70

(52) U.S. Cl. CPC F21V 23/0485; F21Y 2115/10; F21V 29/70; F21V 19/003

(57) ABSTRACT

A touch control lamp includes a shell having an outer surface, on which a plurality of touch control sections are defined, and an accommodation, a circuit board disposed in the accommodation of the shell, and a plurality of light sources and a plurality of capacitive touch sensors, which are mounted on the circuit board in a way that each of the capacitive touch sensors is electrically associated with at least one of the light sources. Each of the capacitive touch sensors spacedly corresponds in position to one of the touch control sections on the outer surface of the shell. The touch control lamp can integrate multiple functions of illumination, decoration and interactive gameplay.

### BACKGROUND OF THE INVENTION

### 1. Field of the Invention

The present invention relates generally to lamps and more particularly, to a touch control lamp, in particular a touch control arched lamp.

### 2. Description of the Related Art

The conventional lamps usually aim at one function which may be emitting white or yellow light for ambient illumination or emitting decorative colored light for beauty. Such lamps are monotonous in function and light-emitting effect thereof.

### SUMMARY OF THE INVENTION

Therefore, it is an objective of the present invention to provide a touch control lamp which can integrate multiple functions of illumination, decoration and interactive gameplay.

To attain the above objective, the present invention provides a touch control lamp which includes a shell, a circuit board, and a plurality of light sources and a plurality of capacitive touch sensors, which are mounted on the circuit board in a way that each of the capacitive touch sensors is electrically associated with at least one of said light sources. The shell has an outer surface, on which a plurality of touch control sections are defined, and an accommodation. The circuit board is disposed in the accommodation of the shell in a way that each of the capacitive touch sensors spacedly corresponds in position to one of the touch control sections on the outer surface of the shell.

Preferably, the touch control lamp further includes a control device for controlling the light sources to function in at least one mode. The light sources include a plurality of top light sources (e.g. RGB LEDs) electrically associated with the capacitive touch sensors for emitting light toward a top surface of the shell, and may, but unlimited to, include a plurality of bottom light sources (e.g. white LEDs) for emitting light toward a bottom surface of the shell. In a predetermined mode, each of the top light sources is switched on and off when the associated touch control section is touched.

As a result, the lamp of the present invention can light up in a variety of modes for illumination or decoration or both, and may be even controlled to provide interactive games.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an assembled perspective view of a touch control lamp according to a preferred embodiment of the present invention;

FIG. 2 is an exploded perspective view of the touch control lamp;

FIG. 3 is a top view of a light device of the touch control lamp;

FIG. 4 is a bottom view of the light device;

FIG. 5 is a sectional view of the touch control lamp; and

FIG. 6 is another assembled perspective view of the touch control lamp.

### DETAILED DESCRIPTION OF THE INVENTION

Hereunder an embodiment of a touch control arched lamp will be described with accompanying drawings for illustrating technical features and structures of the present invention. It is to be understood that the technical features and structures of the present invention can be applied to touch control lamps of different shapes, e.g. linear shape, annular shape, triangular shape, etc.

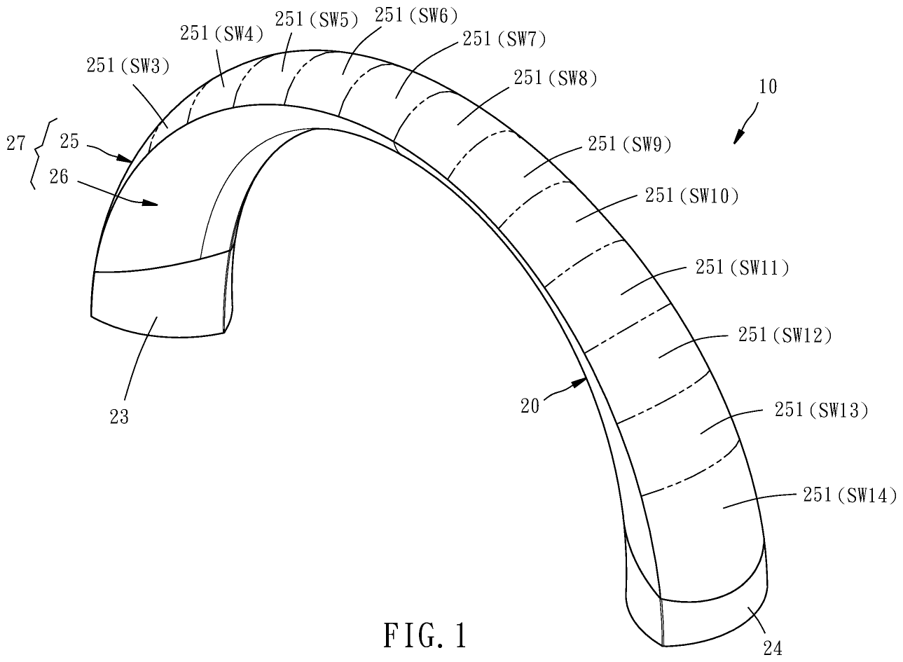

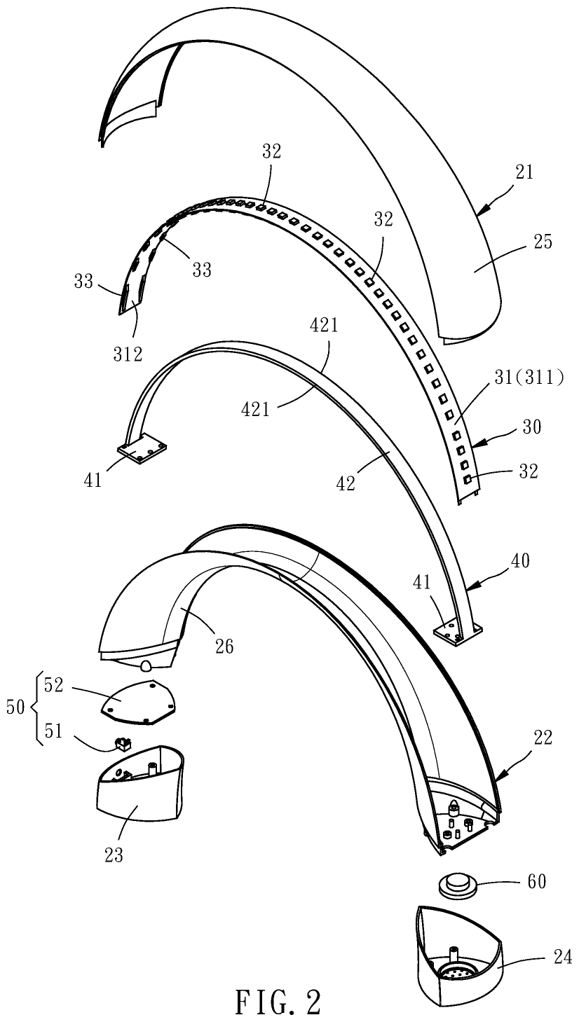

Referring to FIGS. 1-2, a touch control arched lamp 10 according to a preferred embodiment of the present invention includes an arched shell 20, an arched light device 30, an arched light frame 40, a control device 50, and a speaker 60.

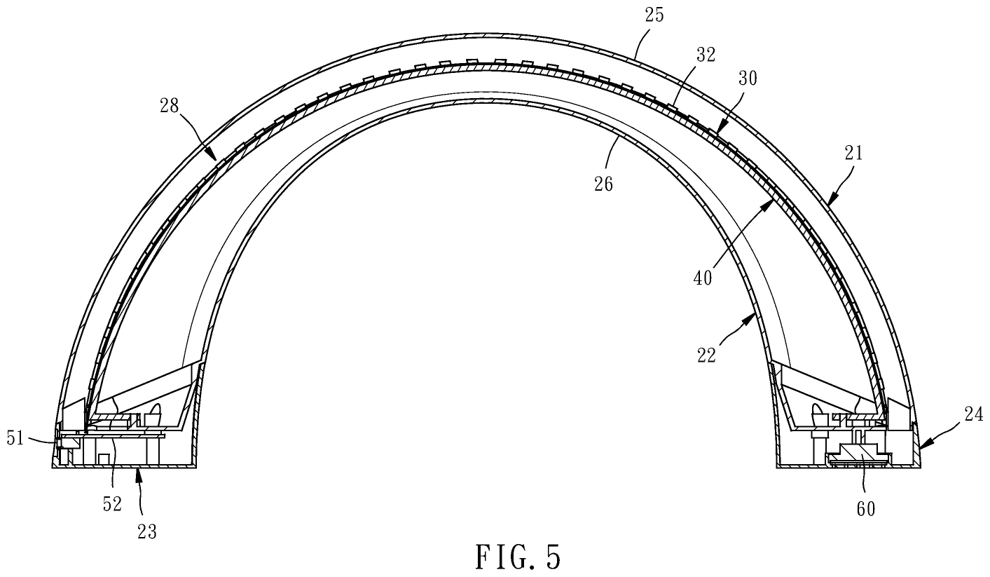

The arched shell 20 is composed of a translucent plastic top diffuser 21, a translucent plastic bottom diffuser 22, and two metal bases 23 and 24. The combination of the top and bottom diffusers 21 and 22 is shaped as a hollow arched structure, two ends of which are fixedly disposed on the two metal bases 23 and 24, respectively. That is, the top and bottom diffusers 21 and 22 combinedly form an arched tube having an outer surface 27 and an inside accommodation 28 as shown in FIG. 5.

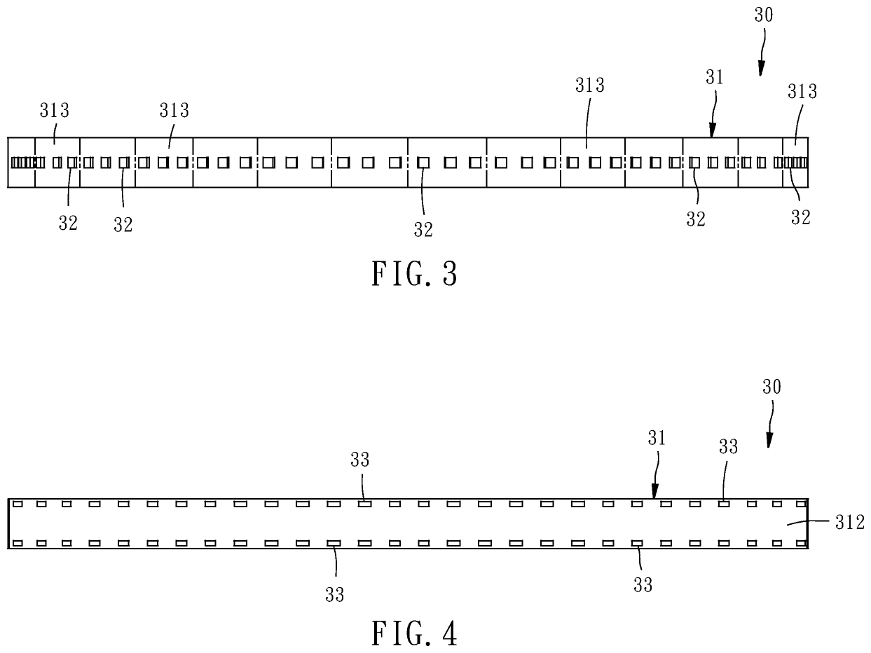

Referring to FIGS. 2-4, the arched light device 30 includes an elongated rectangular circuit board 31, a line of top light sources 32 fixedly disposed on the middle of a top surface 311 of the circuit board 31, and two lines of bottom light sources 33 fixedly disposed along two long edges of a bottom surface 312 of the circuit board 31. There are forty-two top light sources 32 grouped in fourteen sections of the circuit board 31, and each section of the circuit board 31 is provided therein with a capacitive touch sensor 313. Each of the fourteen groups includes three top light sources 32 which are red, green and blue LEDs (RGB LEDs) and also called colored LEDs in the present invention. In other words, the RGB LEDs 32 in the same group are associated with the same capacitive touch sensor 313. The bottom light sources 33 are all white LEDs. The circuit board 31 is originally flat and becomes arched after being disposed on the arched light frame 40.

Referring to FIGS. 2 and 5, the arched light device 30 and the arched light frame 40 are disposed in the arched shell 20 and located between the top and bottom diffusers 21 and 22 at a distance. The arched light frame 40 is made of metal such as aluminum, which serves as a heatsink for dissipating heat generated from the arched light device 30 as well as a structural support for supporting the arched light device 30 in good position and shape, and includes two plates 41 fastened to two ends of the bottom diffuser 22 respectively and an arch 42 extending between the two plates 41. The arched light device 30 are fixedly disposed on the arch 42 of the arched light frame 40 in a way that two ends of the arched light device 30 are fixed to the two plates 41 respectively and the top and bottom surfaces 311 and 312 of the circuit board 31 face toward the top and bottom diffusers 21 and 22 respectively. Therefore, the light of the RGB LEDs 32 is primarily emitted toward a top surface 25 on the top diffuser 21. Besides, the white LEDs 33 are not covered by the arch 42 but located by two sides 421 of the arch 42, thereby primarily emitting light toward a bottom surface 26 on the bottom diffuser 22.

The control device 50 and the speaker 60, which are electrically connected with the arched light device 30, are disposed in the bases 23 and 24 respectively. The control device 50 includes rechargeable batteries (not shown in the drawings), a power jack 51 and a printed circuit board 52, on which electronic components, such as Microcontroller Unit (MCU), capacitive touch sensor, etc., are mounted, for controlling the light sources 32 and 33 and the speaker 60 to function in at least the following five modes. When the user plugs in the lamp 10, the speaker 60 will make a power-on sound. Then the user can select the operating mode of the lamp 10 by simply touching either one of the metal bases 23 and 24, which are provided therein with capacitive touch sensors. In other words, the bases 23 and 24 serve as switches of the lamp 10. Meanwhile, the speaker 60 will make sound for selecting mode. During any mode, double touching the base 23 or 24 will turn the lamp 10 off. The aforesaid and the following control logics are programmatically built in the MCU.

In a first mode, the RGB LEDs 32 display the full rainbow of colors and that rainbow of colors appear to slide slowly from left to right continuously, while the downward facing white LEDs 33 maintain a steady medium brightness. This mode provides some ambient light, while also proving a beautiful moving rainbow display.

In a second mode, the RGB LEDs 32 remain off, and only the white LEDs 33 emit white light. In this mode, holding any switch, i.e. the base 23 or 24, will cause all the white LEDs 33 to slowly dim to low brightness, then brighten slowly back up to full brightness, and continue to repeat this process until the touch is released, at which point the brightness will stay at that value.

In a third mode, the RGB LEDs 32 display the full rainbow of colors, and that rainbow of colors appear to slide slowly from left to right continuously, while the downward facing white LEDs 33 remain off. This mode provides a beautiful rainbow display, while not producing any ambient white light. This mode is excellent for going to sleep, or providing a mood display.

In a fourth mode, the white LEDs 33 remain off, and the RGB LEDs 32 perform a function called “painting,” that will be specified below.

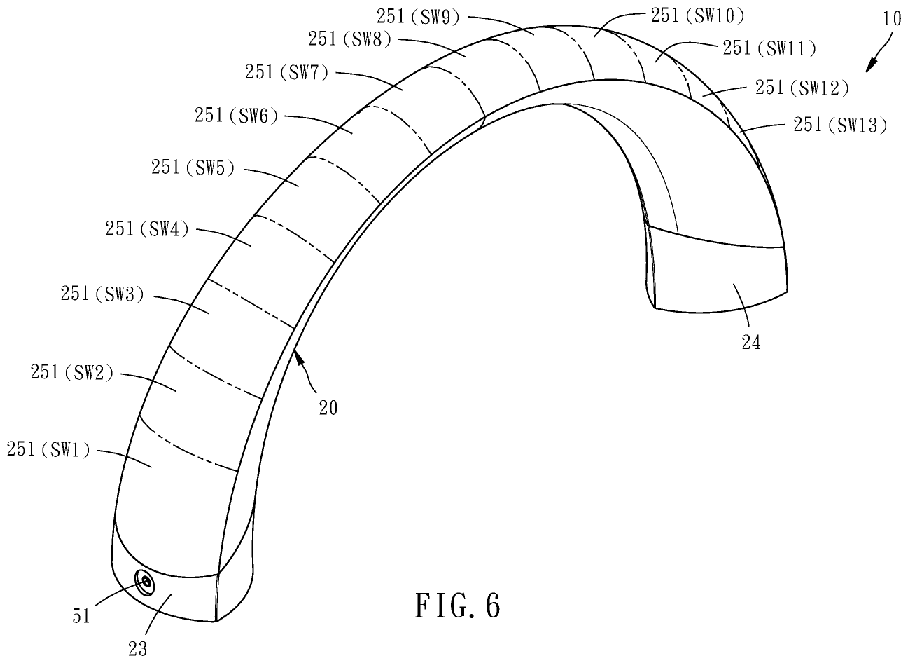

Through the above-described arrangement of the arched sell 20 and the arched light device 30, the top surface 25 of the arched shell 20 is invisibly divided into fourteen touch control sections 251 associated with the capacitive touch sensors 313 respectively, as shown in FIGS. 1 and 6. When anyone of the touch control sections 251 is touched by the finger of the user, the associated capacitive touch sensor 313 can sense the touch to cause the control device 50 to control the RGB LEDs 32 accordingly. In other words, the touch control sections 251 can serve as switches SW1 to SW14 for controlling the associated groups of RGB LEDs 32.

In the aforesaid fourth mode, the switches SW1 and SW14 turn on to red color for example. Holding on to either switch SW1 or switch SW14 causes that switch (touch control section 251) to slowly cycle through all the colors of the rainbow, and releasing that switch causes the displayed color to be chosen. After choosing a specific color, when anyone of the touch control sections 251 is touched, the associated RGB LEDs 32 are switched on to show the chosen color. In other words, touching anyone of the switches SW1 to SW14 turns the switch (touch control section 251) to the chosen color. Such situation is like the finger magically becomes a paint brush (in a virtual manner) to put the chosen color on any switch (touch control section 251) the finger touches. Touching any switch (touch control section 251) that has the same color already turned on in that same chosen color, will cause it to turn off. Meanwhile, the speaker 60 will make sound for painting the switch.

In a fifth mode, the control device 50 can control the RGB LEDs 32 to provide interactive games, such as memory games, like Simon. Action games like a simple version of Pong could also be played.

In brief, the present invention provides on-board LEDs 32, 33 and capacitive touch sensors 313 spacedly and suspendedly arranged inside the shell 20. By means of touching a surface of the shell 20, which corresponds in position to one of the capacitive touch sensors 313, the LEDs associated with the activated capacitive touch sensor 313 may turn on and off. In particular, the touch control sections 251, i.e. switches SW1 to SW14, are defined on the top surface 25 of the outer surface of the shell 20 one after another in succession in a line. With this design, the touch control sections 251 (switches SW1 to SW14) can be sequentially touched by a user's sliding touch motion to turn on and off the top light sources 32 (RGB LEDs) in a sequential manner. Further, in the above-disclosed embodiment, the part of the shell 20 accommodating the circuit board 31 is realized as an arched tube. However, the aforesaid part may be realized as a straight tube, a circle tube, a wavy tube, etc. Besides, the touch control sections of the touch control lamp of the present invention are unlimited to be located on the top surface 25 of the shell 20, but may be located on the bottom surface 26 of the shell 20, i.e. the bottom surface 26 of the bottom diffuser 22, for example. In other words, the capacitive touch sensors 313 may be arranged to sense the touch on the bottom surface 26 of the shell 20 to cause the associated LEDs to turn on and off

What is claimed is:

1. A touch control lamp comprising:
a shell having an outer surface, on which a plurality of touch control sections are defined, and an accommodation; and
a circuit board, on which a plurality of light sources and a plurality of capacitive touch sensors are mounted in a way that each of the capacitive touch sensors is electrically associated with at least one of said light sources;
wherein the circuit board is disposed in the accommodation of the shell in a way that each of the capacitive touch sensors spacedly corresponds in position to one of the touch control sections on the outer surface of the shell.

2. The touch control lamp as claimed in claim 1, wherein the shell has an arched shape; the circuit board is supported on an arched light frame that is suspendedly disposed in the accommodation of the shell in a way that the circuit board is in a form of arched shape with the capacitive touch sensors spaced at a distance from the touch control sections of the outer surface of the shell.

3. The touch control lamp as claimed in claim 2, wherein the arched light frame is made of a metal, such that the arched light frame severs as a heatsink for dissipating heat generated from the light sources.

4. The touch control lamp as claimed in claim 3, wherein the light sources comprise a plurality of top light sources mounted on a top surface of the circuit board for emitting light toward a top surface of the shell, and a plurality of bottom light sources mounted on a bottom surface of the circuit board for emitting light toward a bottom surface of the shell; the arched light frame is attached on a middle of the bottom surface of the circuit board in a way that the bottom light sources are arranged in two lines by two lateral sides of the arched light frame.

5. The touch control lamp as claimed in claim 1, wherein the light sources comprise colored LEDs mounted on a top surface of the circuit board for emitting light toward a top surface of the shell; each of the capacitive touch sensors is electrically associated with at least one of said colored LEDs.

6. The touch control lamp as claimed in claim 1, wherein the light sources comprise white LEDs mounted on a bottom surface of the circuit board for emitting light toward a bottom surface of the shell; the white LEDs are not electrically associated with the capacitive touch sensors.

7. The touch control lamp as claimed in claim 1, wherein the light sources comprise a plurality of top light sources mounted on a top surface of the circuit board for emitting light toward a top surface of the shell, and a plurality of bottom light sources mounted on a bottom surface of the circuit board for emitting light toward a bottom surface of the shell; each of the capacitive touch sensors is electrically associated with at least one of said top light sources.

8. The touch control lamp as claimed in claim 7, wherein the top light sources are colored LEDs and the bottom light sources are white LEDs.

9. The touch control lamp as claimed in claim 1, further comprising a control device electrically connected with the capacitive touch sensors for controlling on and off of the light sources when one of the touch control sections on the outer surface of the shell is touched.

10. The touch control lamp as claimed in claim 9, wherein the shell has an arched shape and the touch control sections are defined on the outer surface of the shell one after another in succession in a line for enabling the touch control sections to be sequentially touched to turn on and off the light sources in a sequential manner.

11. The touch control lamp as claimed in claim 1, wherein the touch control lamp further comprises a control device for controlling the light sources to function in at least one mode; the light sources comprise a plurality of top light sources electrically associated with the capacitive touch sensors for emitting light toward a top surface of the shell; in a said mode controlled by the control device, each of the top light sources is switched on and off when the associated touch control section is touched.

12. The touch control lamp as claimed in claim 11, wherein the top light sources are colored LEDs; in another said mode controlled by the control device, the top light sources emit lights with colors of a rainbow.

13. The touch control lamp as claimed in claim 11, wherein the light sources comprise a plurality of bottom light sources for emitting light toward a bottom surface of the shell.

14. The touch control lamp as claimed in claim 13, wherein the top light sources are colored LEDs, and the bottom light sources are white LEDs; the top light sources emit lights with colors of a rainbow, and the bottom light sources emit white light at the same time.

15. The touch control lamp as claimed in claim 1, further comprising a control device electrically connected with the capacitive touch sensors to control on and off of the light sources to provide an interactive game.
